(19) United States
(12) Patent Application Publication
(10) Pub. No.: US 2026/0173279 A1
(43) Pub. Date: Jun. 18, 2026

(54) DISPLAY APPARATUS

(71) Applicant: LG Display Co., Ltd., Seoul (KR)

(72) Inventors: NohJin MYUNG, Paju-si (KR); SangWoo JIN, Paju-si (KR)

(73) Assignee: LG Display Co., Ltd., Seoul (KR)

(21) Appl. No.: 19/181,284

(22) Filed: Apr. 16, 2025

(30) Foreign Application Priority Data
Dec. 18, 2024 (KR) 10-2024-0189423

(51) Int. Cl. H05K 5/02; H05K 5/03

(52) U.S. Cl. CPC H05K 5/0213; H05K 5/03

(57) ABSTRACT

A display apparatus according to one or more embodiments of the present disclosure comprises a display panel and a rear cover disposed at a rear surface of the display panel. The rear cover includes a first cover disposed at the rear surface of the display panel, a second cover configured to cover the first cover, a coupling member configured to provide an air gap between the first cover and the second cover, and an air guide member disposed between the first cover and the second cover within the air gap. The second cover includes a first hole part and a second hole part configured to be spaced apart from each other along a short-side length direction of the display panel. The air guide member is configured to guide an air flow within the air gap from the first hole part to the second hole part.

### CROSS-REFERENCE TO RELATED APPLICATION

This application claims the benefit of and priority to Korean Patent Application No. 10-2024-0189423 filed on Dec. 18, 2024, the entirety of which is hereby incorporated by reference for all purposes as if fully set forth herein.

### BACKGROUND

### Technical Field

The present disclosure relates to a display apparatus, and more specifically, to a display apparatus capable of improving heat dissipation characteristic.

### Discussion of the Related Art

Display apparatuses are equipped in home appliances or electronic devices such as televisions (TVs), monitors, notebook computers, smartphones, tablet personal computers (PCs), electronic pads, wearable devices, watch phones, portable information devices, navigation devices, and vehicle control display apparatus, or the like, and are used as a screen for displaying an image.

Unlike a liquid crystal display apparatus, a light emitting display apparatus is self-emitting and does not require a separate light source, and thus, there is no problem with the viewing angle. Accordingly, the light emitting display apparatus has received attention as a next generation flat panel display apparatus.

The light emitting display apparatus includes a light emitting display panel, and various methods for dissipating heat generated from the light emitting display panel to an outside are required.

### SUMMARY

The inventors of the present disclosure have recognized the above-mentioned problems, and have performed various experiments for dissipating heat generated from the light emitting display panel to an outside. Through the various experiments, the inventors have invented a display apparatus capable of improving heat dissipation characteristic.

Accordingly, embodiments of the present disclosure are directed to a display apparatus that substantially obviates one or more of the problems due to limitations and disadvantages of the related art.

An aspect of the present disclosure is to provide a display apparatus capable of improving heat dissipation characteristic.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings. c

To achieve these and other aspects of the inventive concepts, as embodied and broadly described herein, a display apparatus comprises a display panel configured to display an image and having long sides and short sides, and a rear cover disposed at a rear surface of the display panel. The rear cover comprises a first cover disposed at the rear surface of the display panel, a second cover configured to cover the first cover, a coupling member configured to provide an air gap between the first cover and the second cover, and an air guide member disposed between the first cover and the second cover within the air gap. The second cover includes a first hole part and a second hole part configured to be spaced apart from each other along a short-side length direction of the display panel. The air guide member is configured to guide an air flow within the air gap from the first hole part to the second hole part.

In another aspect, a display apparatus comprises a display panel configured to display an image, a first cover disposed at a rear surface of the display panel with a gap space therebetween, a second cover disposed at a rear surface of the first cover with an air gap therebetween, a coupling member configured between the first cover and the second cover to provide the air gap, and an air guide member disposed between the first cover and the second cover within the air gap. The second cover includes a first hole part and a second hole part configured to be spaced apart from each other along a short-side length direction of the display panel. The air guide member is configured to increase a flow speed of air flowing from the first hole part to the second hole part within the air gap.

Details of other exemplary embodiments will be included in the detailed description of the disclosure and the accompanying drawings.

The display apparatus according to one or more embodiments of the present disclosure may have improved heat dissipation characteristic.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure and together with the description serve to explain principles of the disclosure.

FIG. 1 is a diagram illustrating a display apparatus according to a first embodiment of the present disclosure.

FIG. 2 is a cross-sectional view taken along I-I′ illustrated in FIG. 1.

FIG. 3 is an exploded perspective view illustrating a display apparatus according to the first embodiment of the present disclosure.

FIG. 4 is a diagram for explaining an air guide member according to a first embodiment of the present disclosure illustrated in FIGS. 2 and 3.

FIG. 5 is a diagram for explaining a second cover and an air guide member according to a first embodiment of the present disclosure illustrated in FIGS. 2 and 3.

FIG. 6 is a diagram for explaining heat dissipation of a display apparatus according to a first embodiment of the present disclosure.

FIG. 7 is an exploded perspective view illustrating a display apparatus according to a second embodiment of the present disclosure.

FIG. 8 is a diagram for explaining a second cover and an air guide member according to a second embodiment of the present disclosure illustrated in FIG. 7.

FIG. 9 is a diagram for explaining heat dissipation of a display apparatus according to a second embodiment of the present disclosure.

FIG. 10 is an exploded perspective view illustrating a display apparatus according to a third embodiment of the present disclosure.

FIG. 11 is a diagram for explaining a second cover and an air guide member according to a third embodiment of the present disclosure illustrated in FIG. 10.

FIG. 12 is a diagram for explaining heat dissipation of a display apparatus according to a third embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and convenience.

### DETAILED DESCRIPTION

Advantages and features of the present disclosure, and implementation methods thereof, are clarified through the aspects described with reference to the accompanying drawings. The present disclosure may, however, be embodied in different forms and should not be construed as limited to the example aspects set forth herein. Rather, these example aspects are examples and are provided so that this disclosure may be thorough and complete to assist those skilled in the art to understand the inventive concepts without limiting the protected scope of the present disclosure.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In a situation where “comprise,” “have,” and “include” described in the present disclosure are used, another part may be added unless “only” is used. The terms of a singular form can include plural forms unless referred to the contrary.

In construing an element, the element is construed as including an error range although there is no explicit description.

In describing a position relationship, for example, when a position relation between two parts is described as “on,” “over,” “under,” and “next,” one or more other parts may be disposed between the two parts unless ‘just’ or ‘direct’ is used.

For the expression that an element is “connected,” “coupled,” or “contact,” to another element, the element may not only be directly connected, coupled, or contacted to another element, but also be indirectly connected, coupled, or contacted to another element with one or more intervening elements interposed between the elements, unless otherwise specified.

For the expression that an element is “contacts” or “overlaps” with another element, the element can not only directly contact, overlap, or the like with another element, but also indirectly contact or overlap with another element with one or more intervening elements disposed or interposed between the elements, unless otherwise specified.

“a first direction,” “a second direction,” “a third direction,” “X-axis direction,” “Y-axis direction,” and “Z-axis direction” should not be construed by a geometric relation only of a mutual vertical relation and may have broader directionality within the range that elements of the present disclosure may act functionally.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, example embodiments of a display apparatus according to the present disclosure will be described in detail with reference to the accompanying drawings. For convenience of description, a scale of each of elements illustrated in the accompanying drawings differs from a real scale, and thus, is not limited to a scale illustrated in the drawings.

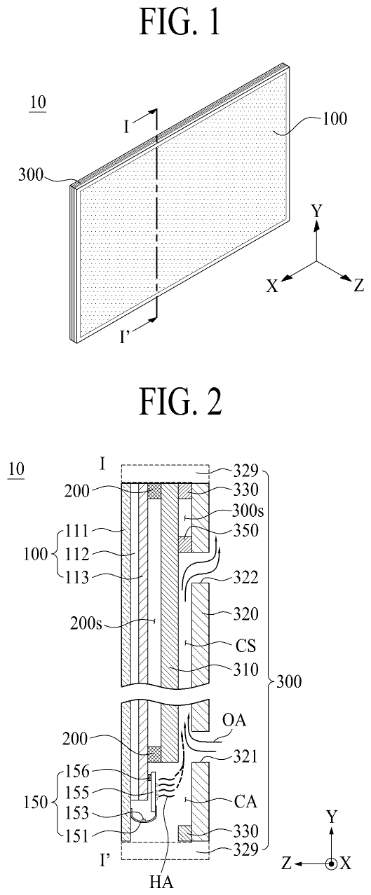

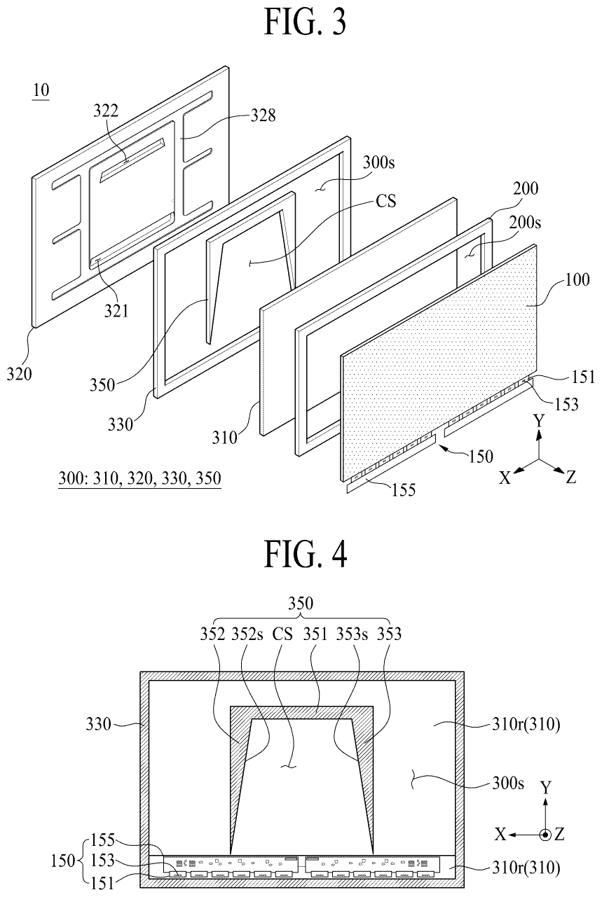

FIG. 1 is a diagram illustrating a display apparatus according to a first embodiment of the present disclosure. FIG. 2 is a cross-sectional view taken along I-I′ illustrated in FIG. 1. FIG. 3 is an exploded perspective view illustrating a display apparatus according to the first embodiment of the present disclosure.

Referring to FIGS. 1 to 3, a display apparatus 10 according to the first embodiment of the present disclosure may include a display panel 100 and a rear cover 300.

The display panel (or a display module) 100 may be configured to display an image. For example, the display panel 100 may output light to display an image. For example, the display panel 100 may be any type of display panel, or a curved display panel, or a flexible display. For example, the display panel 100 may be a liquid crystal display panel, an organic light emitting display panel, a quantum dot light emitting display panel, a micro light-emitting diode display panel, and an electrophoresis display panel, or the like.

The display panel 100 may have a rectangular shape having long sides and short sides, but is not limited thereto. For example, the display panel 100 may include a first long side and a second long side which are parallel to each other, and a first short side and a second short side which are parallel to each other. For example, each of the first and second long sides of the display panel 100 may be parallel to a first direction X or an X-axis direction, and each of the first and second short sides of the display panel 100 may be parallel to a second direction Y or a Y-axis direction.

The display panel (or display module) 100 according to an embodiment may be configured or structured with a bottom emission structure. The display panel (or display module) 100 having the bottom emission structure may include a base member 111, a pixel array part 112, and an encapsulation member 113.

The base member 111 may be configured as one or more of a glass member, a flexible glass member, and a plastic member. For example, the base member 111 may be configured as a polyimide material.

The pixel array part 112 may be configured over the base member 111 to display an image. For example, the pixel array part 112 may include a light emitting device (or a light emitting device layer) disposed over the base member 111. For example, the pixel array part 112 may include a plurality of pixels having a light emitting device (or a light emitting device layer) disposed over the base member 111. For example, each of the plurality of pixels may include a pixel circuit (or a circuit layer) having a thin film transistor connected to the light emitting device. For example, the pixel array part 112 may be a pixel layer, a pixel array layer, a display layer, or a display part, but is not limited thereto.

The encapsulation member 113 may be configured to cover the pixel array part 112. For example, the encapsulation member 113 may be configured to surround the pixel array part 112 and may be configured to prevent oxygen or moisture from penetrating into the light emitting device of the pixel array part 112. For example, the encapsulation member 113 may be disposed (or configured) to cover the pixel array part 112 in a remaining portion (or a display area) except for one edge portion (or a pad portion) of the base member 111. For example, the encapsulation member 113 may include at least one inorganic material layer or may include a metal material. For example, the encapsulation member 113 may be a plate member, an encapsulation plate, a back plate, or a metal plate, but is not limited thereto.

The display panel (or display module) 100 may be configured or structured to have a top emission structure. In this case, the encapsulation member 113 may be disposed at an upper surface of the display panel 100 and may become a screen of the display apparatus 10. The base member 111 may be disposed at a rear surface of the display panel 100 facing the rear cover 300. The encapsulation member 113 may include an encapsulation layer having an organic material layer and an inorganic material layer for preventing moisture penetration, and a transparent glass member (or transparent polyimide member) attached to the encapsulation layer.

The display apparatus 10 according to the first embodiment of the present disclosure may further include a driving circuit part (or a panel driving circuit part) 150.

The driving circuit part 150 may be configured at the rear surface of the display panel 100. The driving circuit part 150 may be configured to be electrically connected to the display panel 100. The driving circuit part 150 may be disposed (or configured) at the rear surface of the display panel 100 and configured to be electrically connected to the pad portion in the display panel 100. For example, the pad portion may be disposed at the one edge portion of the display panel 100. For example, the pad portion may include a plurality of pads electrically connected to pixel signal lines configured in the display panel 100. The plurality of pads may be electrically connected to the driving circuit part 150. For example, the pixel signal lines may be configured to be electrically connected to a pixel circuit which is configured in each of the plurality of pixels.

The driving circuit part 150 according to an embodiment of the present disclosure may include a plurality of flexible films 151, a plurality of data driving integrated circuits 153, and one or more printed circuit boards 155.

Each of the plurality of flexible films 151 may be attached to the pad portion of the display panel 100 by a film attachment process. For example, the plurality of flexible films 151 may be chip on films, but is not limited thereto.

Each of the plurality of data driving integrated circuits 153 may be individually mounted on each of the plurality of flexible films 151. Each of the plurality of data driving integrated circuits 153 may receive pixel data and a timing control signal provided from a control board, convert the pixel data into an analog pixel-based data signal (or a pixel-by-pixel analog data signal or an analog data signal for each pixel), and output converted the analog pixel-based data signal. The pixel-based data signal may be supplied to a signal line (for example, data line) configured at the pixel array part 112 through the flexible film 151 and the pad portion.

The one or more printed circuit boards 155 may be connected to the plurality of flexible films 151 and may be disposed at the rear surface of the display panel 100. For example, the one or more printed circuit boards 155 may be disposed (or fixed) at the one rear edge portion of the display panel 100. The one or more printed circuit boards 155 may be configured to transfer signals and power between components of the driving circuit part 150. For example, the one or more printed circuit boards 155 may be disposed (or fixed) at one rear edge portion of the encapsulation member 113 of the display panel 100 by using an adhesive member 156.

The rear cover 300 may be disposed at the rear surface of the display panel 100. The rear cover 300 may be configured to include a heat dissipation structure for dissipating heat which is generated based on driving of each of the display panel 100 and the driving circuit 150. For example, the rear cover 300 may be configured to include a heat dissipation structure for dissipating heat which is generated based on driving of each of the display panel 100 and the driving circuit 150 according to natural convection activation (or natural convection cooling) by air flow of the internal space.

The rear cover 300 according to an embodiment may include a first cover 310, a second cover 320, a coupling member 330, and an air guide member 350.

The first cover 310 may be disposed at the rear surface of the display panel 100. The first cover 310 may be disposed (or configured) to cover a portion of the rear surface of the display panel 100. For example, the first cover 310 may be disposed (or configured) to cover the encapsulation member 113 of the display panel 100. The first cover 310 may be spaced apart from the rear surface of the display panel 100. For example, the first cover 310 may have a same size as the encapsulation member 113. Thus, the one or more printed circuit boards 155 disposed at the one rear edge portion of the display panel 100 are not covered by the first cover 310.

The first cover 310 according to an embodiment may include a metal material. The first cover 310 may include a plate shape or a flat plate shape. For example, the first cover 310 may be an inner cover, an inner plate, a housing plate, a first rear plate, a first supporting plate, a first supporting member, or a first rear cover.

The second cover 320 may be configured (or disposed) at the rear surface of the first cover 310. The second cover 320 may be disposed to cover the first cover 510. The second cover 320 may be configured (or disposed) to cover a rear surface of the first cover 310 and the one or more printed circuit boards 155. The second cover 320 may be spaced apart from the rear surface of the first cover 310. The second cover 320 may be spaced apart from the rear surface of the first cover 310 with an air gap 300s therebetween. A space between the second cover 320 and the one or more printed circuit boards 155 may be in communication (or connected) with the air gap 300s.

The second cover 320 according to an embodiment may include a metal material or may include a same material as the first cover 320. The second cover 320 may include a plate shape or a flat plate shape, but is not limited thereto. For example, the second cover 320 may be an outer cover, an outer plate, a back cover, a second rear plate, a second supporting plate, a second supporting member, or a second rear cover.

Each of the rear cover 300, the first cover 310, and the second cover 320 may have a same shape as the display panel 100. For example, each of the rear cover 300, the first cover 310, and the second cover 320 may have a rectangular shape having long sides and short sides, but is not limited thereto. For example, each of the rear cover 300, the first cover 310, and the second cover 320 may include a first long side and a second long side which are parallel to each other, and a first short side and a second short side which are parallel to each other. For example, in each of the rear cover 300, the first cover 310, and the second cover 320, the first long side may be a lower side surface or a lower sidewall, the second long side may be an upper side surface or an upper sidewall, the first short side may be a left side surface or a left sidewall, and the second short side may be a right side surface or a right sidewall.

The coupling member (or a joining member) 330 may be configured to provide the air gap 300s between the first cover 310 and the second cover 320. The first cover 310 and the second cover 320 may be coupled (or connected) to each other by the coupling member 330. The coupling member 330 may be disposed along an edge portion of the second cover 320 and may be coupled (or connected) to an edge portion of the first cover 310. For example, the coupling member 330 may have a hollow portion corresponding to the air gap 300s. For example, the coupling member 330 may be configured as one body corresponding to the edge portion of the second cover 320, or may include four coupling members separated to correspond to the first to fourth edge portions of the second cover 320, respectively.

The coupling member 330 according to an embodiment may have a thickness of 1 mm or more. For example, a distance between the first cover 310 and the second cover 320 may be 1 mm or more due to the thickness of the coupling member 330. For example, a fluid (or an air) within the air gap 300s between the first cover 310 and the second cover 320 may have a characteristic of slowing down on a solid surface due to viscosity. For example, when a hydraulic diameter of a channel (or a duct) through which air passes increases (or expands), a flow amount (or a flow rate) of the fluid (or air) may increase due to a decrease (or a reduction) in resistance by the surface of the channel. Accordingly, the coupling member 330 may be configured to have the thickness of 1 mm or more in order to increase the flow amount (or flow rate) of air within the air gap 300s. For example, the coupling member 330 may have a thickness of 3 mm or more.

The coupling member 330 according to an embodiment may be configured to transfer heat of the first cover 310 to the second cover 320. For example, the bonding member 330 may include a conductive material (or conductive particles) or a conductive adhesive member. For example, the coupling member 330 may be a conductive double-sided tape or a conductive double-sided foam tape, but is not limited thereto. The coupling member 330 including the conductive material, and thus, heat conduction efficiency between the first cover 310 and the second cover 320 may be increased. Accordingly, since a conduction path of the heat generated in the display panel 100 is shortened, heat dissipation efficiency of the display panel 100 may be increased, and thus the front temperature of the display panel 100 may be reduced.

The second cover 320 according to an embodiment may include a first hole part 321 and a second hole part 322.

The first hole part 321 and the second hole part 322 may be configured to be spaced apart from each other along a short-side length direction Y of the display panel 100 and to have different sizes. For example, the first hole part 321 may be configured to have a size which is greater than that of the second hole part 322.

The first hole part 321 may be configured between a first long side of the second cover 320 and a center of the second cover 320 so as to penetrate the second cover 320. For example, the first hole part 321 may be configured closer to the first long side of the second cover 320 than the center of the second cover 320. The first hole part 321 may be configured to allow air to introduce (or flow) from an external space of the rear cover 300 (or second cover 320) into the air gap 300s. The first hole part 321 may be formed so as to penetrate the second cover 320 along a thickness direction Z of the second cover 320. Accordingly, air in the external space of the rear cover 300 (or the second cover 320) may be introduced (may flow) into the air gap 300s through the first hole part 321. For example, the first hole part 321 may include one or more holes. For example, the first hole part 321 may be a first hole, a first slit, an inlet part, a lower vent part, an air inlet, a first through hole, a first vent part, or a first air duct.

The second hole part 322 may be configured between a second long side of the second cover 320 and the center of the second cover 320 so as to penetrate the second cover 320. For example, the second hole part 322 may be configured closer to the second long side of the second cover 320 than to the center of the second cover 320. The second hole part 322 may be configured to allow air to flow out (or be discharged) to the external space of the rear cover 300 (or the second cover 320). The second hole part 322 may be formed so as to penetrate the second cover 320 along the thickness direction Z of the second cover 320. Accordingly, air (or high-temperature air) within the air gap 300s may flow out (or be discharged or dissipated) to the external space of the rear cover 300 (or the second cover 320) through the second hole part 322 by natural convection phenomenon in which air rises in the opposite direction to the direction of gravity due to buoyancy. For example, the second hole part 322 may include one or more holes. For example, the second hole part 322 may include a second hole, a second slit, an outlet, an upper vent part, an air outlet, a second through hole, a second vent part, or a second air duct.

The second cover 320 according to an embodiment may further include a reinforcing portion (or a forming portion) 328. For example, the reinforcing portion 328 may be configured to reinforce the rigidity of the second cover 320. The reinforcing portion 328 may be formed concavely from a first surface (or a front surface) of the second cover 320, but is not limited thereto. For example, the reinforcing portion 328 may include one or more horizontal reinforcing portions (or horizontal forming portions) and one or more vertical reinforcing portions (or vertical forming portions). For example, a portion of the one or more horizontal reinforcing portions may be connected to the one or more vertical reinforcing portions.

The second cover 320 according to an embodiment may further include a sidewall portion 329. The sidewall portion 329 may be connected to an edge portion of the second cover 320 or may be bent from the edge portion of the second cover 320. The sidewall portion 329 may be configured to surround lateral surfaces of the coupling member 330, lateral surfaces of the first cover 310, and lateral surfaces of the display panel 100.

The air guide member 350 may be disposed (or interposed) or configured between the first cover 310 and the second cover 320 within the air gap 300s. For example, the air guide member 350 may be configured or structured to increase a flow speed (or a flow rate) of air flowing in a direction from the first hole part 321 to the second hole part 322 within the air gap 300s. For example, the air guide member 350 may be configured or structured to reduce an air pressure around the second hole part 322 so as to rapidly induce a speed (or the flow speed) of air in which heat (or high-temperature air of the air gap 300s is discharged to the external space through the second hole part 322.

The air guide member 350 may include a conductive material (or conductive particles) or a conductive adhesive member. For example, the air guide member 350 may be a conductive double-sided tape or a conductive double-sided foam tape, but is not limited thereto. The air guide member 350 includes a conductive material, and thus, the heat conduction efficiency between the first cover 310 and the second cover 320 may be increased. Accordingly, since a conduction path of heat which is generated in the display panel 100 is shortened, the heat dissipation efficiency of the display panel 100 may be increased, and thus a front temperature of the display panel 100 may be reduced (or decreased). For example, the air guide member 350 may include a same conductive material as the coupling member 330 or may include the conductive adhesive member, but is not limited thereto. For example, one or more of the coupling member 330 and the air guide member 350 may include a conductive material or a conductive adhesive member.

For the same reason as the coupling member (330), the air guide member 350 may be configured to have a thickness of 1 mm or more in order to increase the flow amount (or flow rate) of the air within the air gap 300s. For example, the air guide member 350 may have a thickness of 3 mm or more. For example, the air guide member 350 may have a same thickness as the coupling member 330.

The air guide member 350 may be configured to provide a convection space CS between the first hole part 321 and the second hole part 322 within the air gap 300s. For example, the convection space CS may narrow from the first hole part 321 to the second hole part 322. For example, the convection space CS may progressively narrow in a direction from the first hole part 321 toward the second hole part 322. For example, the convection space CS may narrow (or progressively narrow in a direction) from a lower side to an upper side of the second cover 320 along the short-side length direction Y of the second cover 320. For example, the convection space CS may narrow with (or progressively narrow in a direction) increasing distance from one or more printed circuit boards 155 along the short-side length direction Y of the second cover 320. The air guide member 350 may be configured or structured to reduce the air pressure around the second hole part 322 so as to rapidly induce the speed (or the flow speed) of air in which the heat (or high-temperature air) of the convection space CS is discharged to the external space through the second hole part 322.

According to an embodiment, the heat transferred from the display panel 100 and the driving circuit 150 to the rear cover 300 may be dissipated according to a double-sided cooling effect due to natural convection and external convection in the convection space CS formed (or provided) by the air guide member 350 and the first hole part 321 and the second hole part 322. Accordingly, the display apparatus 10 according to the first embodiment of the present disclosure may have improved heat dissipation characteristics (or heat dissipation performance) due to an increase in heat dissipation surface area, and the temperature of the front surface of the display panel 100 may be reduced due to activation of natural convection in the air gap 300s.

The display apparatus 10 according to the first embodiment of the present disclosure may further include a connection member 200.

The connection member 200 may be configured (or disposed) between the display panel 100 and the rear cover 500. The connection member 200 may be configured (or disposed) between the display panel 100 and the first cover 310. The connection member 200 may be configured to separate the rear cover 300 (or the first cover 310) from the rear surface of the display panel 100. The connection member 200 may be configured between the rear surface of the display panel 100 and the rear cover 300 (or the first cover 310) to provide a gap space 200s.

The rear cover 300 (or the first cover 310) may be coupled or connected to the display panel 100 by the connection member 200. The rear cover 300 (or the first cover 310) may be coupled or connected to a rear edge portion of the encapsulation member 113 by using the connection member 200.

For the same reason as the connection member 330 described above, the connection member 200 according to an embodiment may be configured to have a thickness of 1 mm or more in order to increase the flow amount of air within the gap space 200s. For example, the connection member 200 may have a thickness of 3 mm or more. For example, the connection member 200 may have a same thickness as the connection member 330, but is not limited thereto.

The connection member 200 according to an embodiment may include one or more of an adhesive, a double-sided tape, a double-sided foam tape, and a double-sided cushion tape, but is not limited thereto. For example, the connection member 200 may include a same conductive material as one or more of the coupling member 320 and the air guide member 350 or may include a conductive adhesive member in order to increase the thermal conductivity efficiency between the display panel 100 and the rear cover 300 (or the first cover 310).

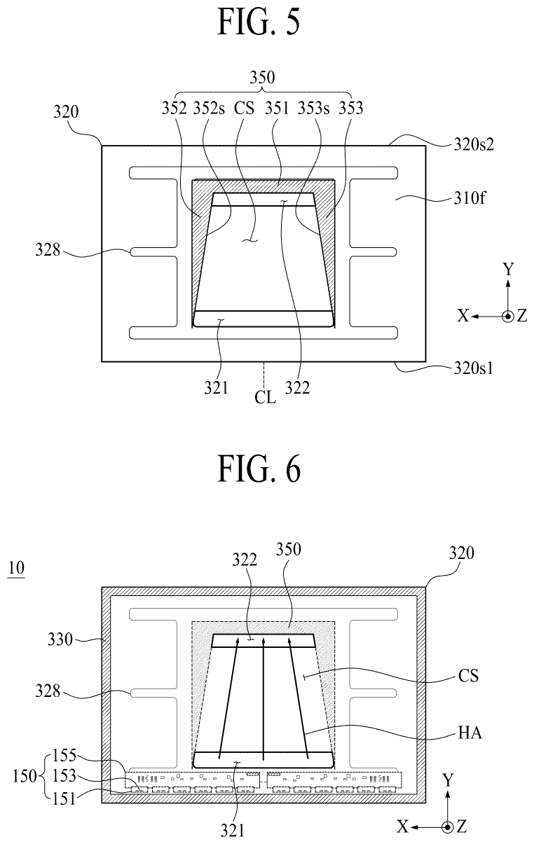

FIG. 4 is a diagram for explaining an air guide member according to a first embodiment of the present disclosure illustrated in FIGS. 2 and 3. FIG. 5 is a diagram for explaining a second cover and an air guide member according to a first embodiment of the present disclosure illustrated in FIGS. 2 and 3.

Referring to FIGS. 2, 4, and 5, the air guide member 350 according to the first embodiment of the present disclosure may be connected (or coupled) to a rear surface 310r of the first cover 310 and a front surface 320f of the second cover 320. For example, a first surface (or front surface) of the air guide member 350 may be connected (or coupled) to the rear surface 310r of the first cover 310, and a second surface (or rear surface) of the air guide member 350 may be connected (or coupled) to the front surface 320f of the second cover 320.

The air guide member 350 according to the first embodiment of the present disclosure may include a first guide portion 351, a second guide portion 352, and a third guide portion 353.

The first guide portion (or a first air guide portion) 351 may be disposed between the second long side 310s2 of the second cover 320 and the second hole part 322. For example, the first guide portion 351 may be disposed closer to the second hole part 322 than to the second long side 310s2 of the second cover 320. For example, the first guide portion 351 may have a line shape parallel to the second long side 310s2 of the second cover 320. A center of the first guide portion 351 may be disposed on a center line CL of the long sides 320s1 and 32 0s2 of the second cover 320. For example, the first guide portion 351 may be symmetrical (or horizontal symmetrical) with respect to the center line CL of the long sides 320s1 and 320s2 of the second cover 320.

The second guide portion (or a second air guide portion) 352 may be configured (or disposed) to be connected to the first side of the first guide portion 351 and extend to the first side of the first hole part 321. For example, the second guide portion 352 may be disposed at the first side of the first hole part 321, the first side of the second hole part 322, and a region between the first side of the first hole part 321 and the first side of the second hole part 322. For example, the second guide portion 352 and the first guide portion 351 may be configured as a single body.

With respect to a long-side length direction X of the display panel 100 (or the second cover 320), a cross-sectional size (or a cross-sectional area) of the second guide portion 352 may decrease (or progressively decrease in a direction) from the second hole part 322 to (or toward) the first hole part 321. The second guide portion 352 may be disposed between the first hole part 321 and the second hole part 322 and may include an inclined surface 352s which is inclined (or angled) from a short-side length direction Y of the display panel 100 (or the second cover 320). For example, the second guide portion 352 may extend (or extend in a direction) from the first side of the second hole part 322 to (or toward) the first side of the first hole part 321 and may include an inclined surface 352s which is inclined from the short-side length direction Y of the display panel 100 (or the second cover 320). For example, the second guide portion 352 may extend to have a triangular shape having the inclined surface 352s. For example, the second guide portion 352 may extend to have a right-angled triangular shape having the inclined surface 352s. For example, an end of the second guide portion 352 may be disposed on the first side of the first hole part 321 adjacent to one or more printed circuit boards 155 and may be pointed (or sharpened).

The third guide portion (or a third air guide portion) 353 may be configured (or disposed) to be connected to a second side of the first guide portion 351 opposite the first side of the first guide portion 351 and extend to a second side of the first hole part 321 opposite the first side of the first hole part 321. For example, the third guide portion 353 may be disposed at a second side of the first hole part 321, the second side of the second hole part 322, and a region between the second side of the first hole part 321 and the second side of the second hole part 322. For example, the third guide portion 353 and the first guide portion 351 may be formed as a single body. For example, the first to third guide sections 351, 352, and 353 may be formed as one body.

With respect to the long-side length direction X of the display panel 100 (or the second cover 320), a cross-sectional size (or a cross-sectional area) of the third guide portion 353 may decrease (or progressively decrease in a direction) from the second hole part 322 to (or toward) the first hole part 321. The third guide portion 353 may be disposed between the first hole part 321 and the second hole part 322 and may include an inclined surface 353s which is inclined (or angled) from the short-side length direction Y of the display panel 100 (or the second cover 320). For example, the third guide portion 353 may extend (or extend in a direction) from the second side of the second hole part 322 to the second side of the first hole part 321 and may include an inclined surface 353s which is inclined from the short-side length direction Y of the display panel 100 (or the second cover 320). For example, the third guide portion 353 may extend to have a triangular shape having the inclined surface 353s. For example, the third guide portion 353 may extend to have a right-angled triangular shape having the inclined surface 353s. For example, an end of the third guide portion 353 may be disposed on the second side of the first hole part 321 adjacent to the one or more printed circuit boards 155 and may be pointed (or sharpened).

A distance between the second guide portion 352 and the third guide portion 353 may decrease (or progressively decrease in a direction) from the first hole part 321 to (or toward) the second hole part 322 along the short-side length direction Y of the display panel 100 (or the second cover 320). The distance between the second guide portion 352 and the third guide portion 353 may decrease (or progressively decrease in a direction) from the first hole part 321 to (or toward) the second hole part 322 due to the inclined surfaces 352s and 353s. The distance between the inclined surface 352s of the second guide portion 352 and the inclined surface 353s of the third guide portion 353 may decrease (or progressively decrease in a direction) from the first hole part 321 to (or toward) the second hole part 322.

The first to third guide portions 351, 352, and 353 may provide a convection space CS between the first hole part 321 and the second hole part 322 within the air gap 300s. In the convection space CS, the distance between the second guide portion 352 and the third guide portion 353 may decrease (or progressively decrease in a direction) from the first hole part 321 to (or toward) the second hole part 322. Accordingly, the convection space CS may narrow (or progressively narrow in a direction) from the first hole part 321 to (or toward) the second hole part 322 along the short-side length direction Y of the display panel 100 (or the second cover 320).

One side of the first hole part 321 may be connected to (or communicated with) the air gap 300s. The remaining part except for the one side of the convection space CS corresponding to the first hole part 321 may be spatially separated from the air gap 300s by the first to third guide portions 351, 352, and 353.

The second guide portion 352 and the third guide portion 353 may be symmetrical (or horizontal symmetrical) with respect to the center line CL of the long side 320s1 and 320s2 of the second cover 320.

According to an embodiment, one sidewall (or a lower wall) of the first guide portion 351 may be located (or aligned) at an upper side of the second hole part 322 which is parallel to the second long side 310s2 of the second cover 320. For example, the first guide portion 351 may be configured to block air of the convection space CS from flowing through the second hole part 322 toward the second long side 310s2 of the second cover 320.

The one sidewall (or lower wall) of the first guide portion 351, one side of the inclined surface 352s of the second guide portion 352, and one side of the inclined surface 353s of the third guide portion 353 may provide (or define) an upper side space (or a top space) of the convection space CS. An end of the inclined surface 352s of the second guide portion 352 adjacent to the first hole part 321 and an end of the inclined surface 353s of the third guide portion 353 may provide (or define) a lower side space (or a bottom space) of the convection space CS.

The first hole part 321 may be disposed (or configured) in a convection space CS defined (or provided) by the air guide member 350. The first hole part 321 may be disposed (or configured) in the lower side space (or bottom space) of the convection space CS. The first hole part 321 may be disposed (or configured) inside the air guide member 350. The first side and the second side of the first hole part 321 may be surrounded by the air guide member 350. The first side of the first hole part 321 may be surrounded by an end of the inclined surface 352s of the second guide member 352, and the second side of the first hole part 321 may be surrounded by an end of the inclined surface 353s of the third guide member 353.

The first hole part 321 may be configured between the first long side 320s1 of the second cover 320 and the center of the second cover 320 so as to penetrate the second cover 320. The first hole part 321 may be configured to be adjacent to the one or more printed circuit boards 155. For example, the one or more printed circuit boards 155 may be disposed at a rear edge portion of the display panel 100 adjacent to the first hole part 321. The first hole part 321 may be configured to penetrate the second cover 320 along the thickness direction Z of the second cover 320. Accordingly, the external space of the second cover 320 may be communicated with (or connected to) the convection space CS and/or the air gap 300s through the first hole part 321.

The first hole part 321 may have a line shape parallel to the second long side 310s2 of the second cover 320. A center of the first hole part 321 may be disposed on the center line CL of the long sides 320s1 and 320s2 of the second cover 320. For example, the first hole part 321 may be symmetrical (or horizontal symmetrical) with respect to the center line CL of the long sides 320s1 and 320s2 of the second cover 320. The first hole part 321 may be disposed between the end of the inclined surface 352s of the second guide portion 352 and the end of the inclined surface 353s of the third guide portion 353. For example, with respect to the long-side length direction X of the display panel 100 (or the second cover 320), a length of the first hole part 321 may correspond to a distance between the end of the inclined surface 352s of the second guide portion 352 and the end of the inclined surface 353s of the third guide portion 353.

The second hole part 322 may be disposed (or configured) in a convection space CS defined (or provided) by the air guide member 350. The second hole part 322 may be disposed (or configured) inside the air guide member 350. The second hole part 322 may be disposed (or configured) to be spaced apart from the first hole part 321 along the short-side length direction Y of the display panel 100 (or the second cover 320) in the convection space CS. The second hole part 322 may be disposed (or configured) in the upper side space (or top space) of the convection space CS. The remaining portion except for one side (or lower side) of the second hole part 322 may be surrounded by the air guide member 350.

The second hole part 322 may be configured between the second long side 320s2 of the second cover 320 and the center of the second cover 320 so as to penetrate the second cover 320. The second hole part 322 may be configured to penetrate the second cover 320 along the thickness direction Z of the second cover 320. Accordingly, the external space of the second cover 320 may be communicated with (or connected to) the convection space CS and/or the air gap 300s through the second hole part 322.

The second hole part 322 may have a line shape parallel to the second long side 310s2 of the second cover 320. A center of the second hole part 322 may be disposed on the center line CL of the long sides 320s1 and 320s2 of the second cover 320. For example, the second hole 321 may be symmetrical (or horizontal symmetrical) with respect to the center line CL of the long sides 320s1 and 320s2 of the second cover 320. The second hole part 322 may be disposed between the one side of the inclined surface 352s of the second guide portion 352 and the one side of the inclined surface 353s of the third guide portion 353. For example, with respect to the long-side length direction X of the display panel 100 (or the second cover 320), a length of the second hole part 322 may correspond to a distance between the one side of the inclined surface 352s of the second guide portion 352 and the one side of the inclined surface 353s of the third guide portion 353.

According to an embodiment, with respect to the short-side length direction Y of the display panel 100 (or the second cover 320), an extension line of the center of the first hole part 321 may be located (or aligned) at the center of the second hole part 322. The first hole part 321 may have a size which is greater than the second hole part 322. For example, the first hole part 321 may have a width and a length which are greater than the second hole part 322. For example, the first hole part 321 may be wider and longer than the second hole part 322.

FIG. 6 is a diagram for explaining heat dissipation of a display apparatus according to a first embodiment of the present disclosure.

Referring to FIGS. 2 and 6, the display apparatus 10 according to the first embodiment of the present disclosure includes the convection space CS which is formed (or provided) between the first cover 310 and the second cover 320 by the air guide member 350, the first hole part 321, and the second hole part 322, and thus, the heat generated by driving each of the display panel 100 and the driving circuit part 150 may be dissipated by natural convection phenomenon in the convection space CS.

The heat generated by driving the display panel 100 is transferred to the first cover 310 of the rear cover 300 through the gap space 200s, and the heat transferred to the first cover 310 and the heat (or high-temperature air) HA generated by driving the driving circuit part 150 may be dissipated according to the natural convection phenomenon of external air OA that flows into the convection space CS from the external space through the first hole part 321 and flows out (or discharged) to the external space through the second hole part 322. Accordingly, the display apparatus 10 according to the first embodiment of the present disclosure may dissipate the heat transferred to the first cover 310 and the heat HA generated by driving the driving circuit part 150 according to the double-sided cooling effect due to natural convection and external convection in the convection space CS.

Therefore, the display apparatus 10 according to the first embodiment of the present disclosure may further improve heat dissipation characteristics, and the heat dissipation characteristics (or heat dissipation performance) may be improved due to an increase in the heat dissipation surface area, and the temperature of the front surface of the display panel 100 may be reduced due to activation of natural convection in the air gap 300s.

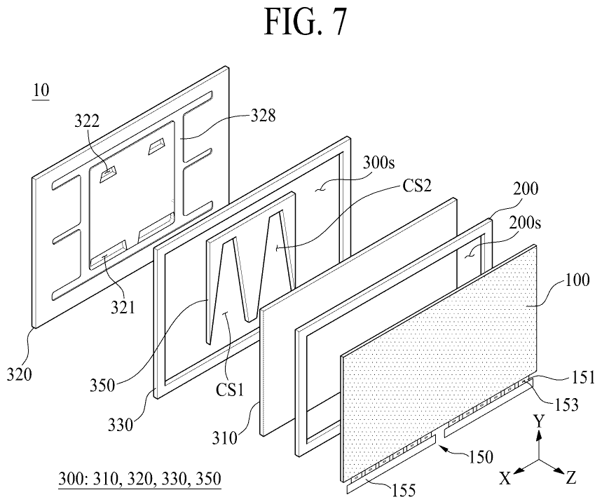

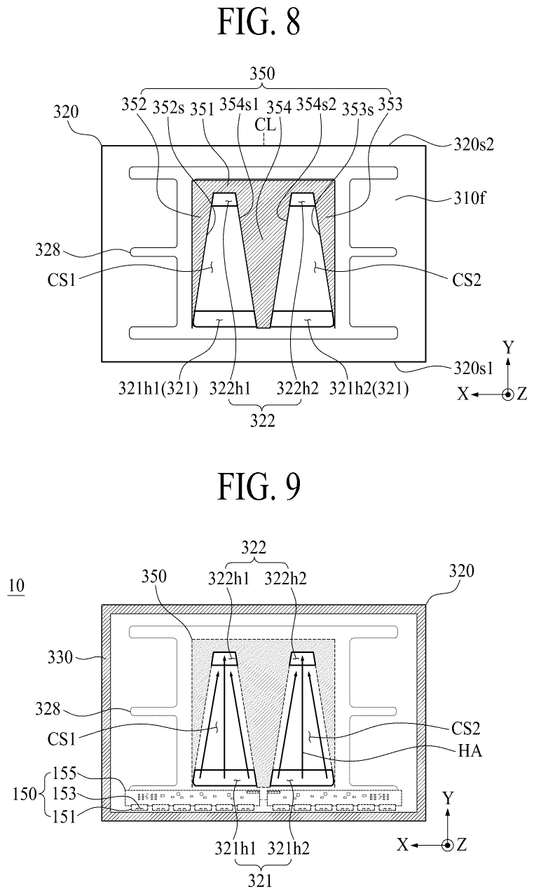

FIG. 7 is an exploded perspective view illustrating a display apparatus according to a second embodiment of the present disclosure. FIG. 8 is a diagram for explaining a second cover and an air guide member according to a second embodiment of the present disclosure illustrated in FIG. 7. FIGS. 7 and 8 illustrate an embodiment implemented by modifying the second cover and the air guide member in the display apparatus described above with reference to FIG. 6. In the following description, therefore, the second cover and the air guide member will be only described, the other elements are referred to by same reference numerals as FIGS. 2 and 6, and thus, their repetitive descriptions are omitted or will be briefly given.

Referring to FIGS. 7 and 8, in the display apparatus 10 according to the second embodiment of the present disclosure, the first hole part 321 configured at the rear cover 300 (or the second cover 320) may include a 1-1^{th} hole 321h1 and a 1-2^{th} hole 321h1.

The 1-1^{th} hole part 321h1 and the 1-2^{th} hole 321h2 may be configured to be spaced apart from each other along a long-side length direction X of the display panel 100 and to penetrate the second cover 320. For example, each of the first-first hole part 321h1 and the first-second hole 321h2 may be configured to have a same size. Each of the 1-1^{th} hole part 321h1 and the 1-2^{th} hole 321h2 may be configured to be adjacent to one or more printed circuit boards 155. For example, the 1-1^{th} hole part 321h1 and the 1-2^{th} hole 321h2 may be symmetrical (or horizontal symmetrical) with respect to a center line CL of the long sides 320s1 and 320s2 of the second cover 320. Each of the 1-1^{th} hole part 321h1 and the 1-2^{th} hole 321h2 may be formed to penetrate the second cover 320 along the thickness direction Z of the second cover 320. Accordingly, air in the external space of the rear cover 300 (or the second cover 320) may be introduced (or flowed) into the air gap 300s through each of the 1-1^{th} hole part 321h1 and the 1-2^{th} hole 321h2.

In the display apparatus 10 according to the second embodiment of the present disclosure, the second hole part 322 configured at the rear cover 300 (or the second cover 320) may include a 2-1^{th} hole 322h1 and a 2-2^{th} hole 322h2.

The 2-1^{th} hole 322h1 and the 2-2^{th} hole 322h2 may be configured to be spaced apart from each other along the long-side length direction X of the display panel 100 and to penetrate the second cover 320. For example, each of the 2-1^{th} hole 322h1 and the 2-2^{th} hole 322h2 may be configured to have a same size. Each of the 2-1^{th} hole 322h1 and the 2-2^{th} hole 322h2 may be configured between the second long side of the second cover 320 and the center of the second cover 320.

Each of the 2-1^{th} hole 322h1 and the 2-2^{th} hole 322h2 may be configured closer to the second long side of the second cover 320 than to the center of the second cover 320. For example, the 2-1^{th} hole 322h1 and the 2-2^{th} hole 322h2 may be symmetrical (or horizontal symmetrical) with respect to the center line CL of the long sides 320s1 and 320s2 of the second cover 320. Each of the 2-1^{th} hole 322h1 and the 2-2^{th} hole 322h2 may be formed to penetrate the second cover 320 along the thickness direction Z of the second cover 320. Thereby, the air (or high-temperature air) within the air gap 300s may flow out (or be discharged or dissipated) to the external space of the rear cover 300 (or the second cover 320) through the 2-1^{th} hole 322h1 and the 2-2^{th} hole 322h2 by natural convection phenomenon in which air rises in the opposite direction to the direction of gravity due to buoyancy.

Each of the 1-1^{th} hole 321h1, the 1-2^{th} hole 321h2, the 2-1^{th} hole 322h1, and the 2-2^{th} hole 322h2 may have a line shape parallel to the second long side 310s2 of the second cover 320. The 1-1^{th} hole 321h1 may have a size which is greater than the 2-1^{th} hole 322h1. The 1-2^{th} hole 321h2 may have a size which is greater than the 2-2^{th} hole 322h2. The 1-1^{th} hole 321h1 may have a width and a length which are greater than the 2-1^{th} hole 322h1. The 1-2^{th} hole 321h2 may have a width and a length which are greater than the 2-2^{th} hole 322h2. For example, with respect to a short-side length direction Y of the display panel 100, an extension line of a center of the 1-1^{th} hole 321h1 may be located (or aligned) at a center of the 2-1^{th} hole part 322h1, and an extension line of a center of the 1-2^{th} hole 321h2 may be located (or aligned) at a center of the 2-2^{th} hole part 322h2.

The air guide member 350 according to the second embodiment of the present disclosure may be configured to provide (or form) a first convection space CS1 and a second convection space CS2 within the air gap 300s.

The first convection space CS1 may be provided (or formed) between the 1-1^{th} hole 321h1 and the 2-1^{th} hole part 322h1 within the air gap 300s.

The first convection space CS1 may be provided (or formed) between the 1-1^{th} hole 321h1 and the 2-1^{th} hole 322h1 within the air gap 300s. For example, the first convection space CS1 may narrow (or progressively narrow in a direction) from the 1-1^{th} hole 321h1 to (or toward) the 2-1^{th} hole 322h1. For example, the first convection space CS1 may narrow (or progressively narrow in a direction) from a lower side to (or toward) an upper side of the second cover 320 along a short-side length direction Y of the second cover 320. For example, the first convection space CS1 may narrow with (or progressively narrow in a direction) increasing distance from the one or more printed circuit boards 155 along the short-side length direction Y of the second cover 320.

The second convection space CS2 may be provided (or formed) between the 1-2^{th} hole 321h2 and the 2-2^{th} hole 322h2 within the air gap 300s. For example, the second convection space CS2 may narrow (or progressively narrow in a direction) from the 1-2^{th} hole 321h2 to (or toward) the 2-2^{th} hole 322h2. For example, the second convection space CS2 may narrow (or progressively narrow in a direction) from the lower side to (or toward) the upper side of the second cover 320 along the short-side length direction Y of the second cover 320. For example, the second convection space CS2 may narrow with (or progressively narrow in a direction) increasing distance from the one or more printed circuit boards 155 along the short-side length direction Y of the second cover 320.

The air guide member 350 according to the second embodiment of the present disclosure may be configured or structured to reduce the air pressure around the 2-1^{th} hole 322h1 in order to rapidly induce a speed (or a flow speed) of air in which heat (or high-temperature air) of the first convection space CS1 is discharged to the external space through the 2-1^{th} hole 322h1. In addition, the air guide member 350 according to the second embodiment of the present disclosure may be configured or structured to reduce the air pressure around the 2-2^{th} hole 322h2 in order to rapidly induce a speed (or a flow speed) of air in which heat (or high-temperature air) of the second convection space CS2 is discharged to the external space through the 2-2^{th} hole 322h2.

The air guide member 350 according to the first embodiment of the present disclosure may include a first guide portion 351, a second guide portion 352, a third guide portion 353, and a fourth guide portion 354.

The first guide portion (or a first air guide portion) 351 may be disposed between the second long side 310s2 of the second cover 320 and the second hole part 322. For example, the first guide portion 351 may be disposed closer to the second hole part 322 than to the second long side 310s2 of the second cover 320. For example, the first guide portion 351 may have a line shape parallel to the second long side 310s2 of the second cover 320. A center of the first guide portion 351 may be disposed at the center line CL of the long sides 320s1 and 320s2 of the second cover 320. For example, the first guide portion 351 may be symmetrical (or horizontal symmetrical) with respect to the center line CL of the long sides 320s1 and 320s2 of the second cover 320.

The second guide portion (or a second air guide portion) 352 may be configured (or disposed) to be connected to the first side of the first guide portion 351 and to be extended to a first side of the 1-1th hole 321h1 of the first hole part 321. Except for that the second guide portion 352 is connected to the first side of the first guide portion 351 and is extended to the first side of the 1-1^{th} hole 321h1, the second guide portion 352 is substantially a same as the second guide portion 352 described above with reference to FIGS. 3 to 6, and thus, the repetitive description thereof is omitted.

The third guide portion (or a third air guide portion) 352 may be configured (or disposed) to be connected to a second side of the first guide portion 351 and may be extended to a first side of the 1-2^{th} hole 321h2 of the first hole part 321. Except for that the third guide portion 353 is connected to the second side of the first guide portion 352 and is extended to the first side of the 1-2^{th} hole 321h2, the third guide portion 353 is substantially a same as the third guide portion 353 described above with reference to FIGS. 3 to 6, and thus, the repetitive description thereof is omitted.

The fourth guide portion (or a fourth air guide portion) 354 may be configured (or disposed) to be connected to a third side of the first guide portion 351 corresponding to a middle region between the 2-1^{th} hole 322h1 and the 2-2^{th} hole 322h2, and to be extended to a region between a second side of the 1-1^{th} hole 321h1 and a second side of the 1-2^{th} hole 321h2. The fourth guide portion 354 may be symmetrical (or horizontal symmetrical) with respect to the center line CL of the long sides 320s1 and 320s2 of the second cover 320.

With respect to a long-side length direction X of the display panel 100 (or the second cover 320), a cross-sectional size (or a cross-sectional area) of the fourth guide portion 354 may decrease (or progressively decrease in a direction) from the second hole part 322 to (or toward) the first hole part 321. One side (or an upper side) of the fourth guide portion 354 may be disposed between the 2-1^{th} hole 322h1 and the 2-2^{th} hole 322h2 and may be connected to a third side of the first guide portion 351. The other side (or a lower side) of the fourth guide portion 354 may be disposed between the 1-1^{th} hole 321h1 and the 1-2^{th} hole 321h2 and may be disposed to be adjacent to the one or more printed circuit boards 155.

The fourth guide portion 354 may include first and second inclined surfaces 354s1 and 354s2 inclined from the short-side length direction Y of the display panel 100 (or the second cover 320). For example, the fourth guide portion 354 may be extended to have an equilateral trapezoidal shape having the first and second inclined surfaces 354s1 and 354s2. For example, the fourth guide portion 354 and the first guide portion 351 may be configured as one body. For example, the first to fourth guide portions 351, 352, 353, and 354 may be configured as one body.

The first, second, and fourth guide portions 351, 352, and 354 may provide a first convection space CS1 within the air gap 300s. For example, the first convection space CS1 within the air gap 300s may be defined (or provided) to be surrounded by a first portion of the first guide portion 351, the second guide portion 352, and the fourth guide portion 354. One side of each of the first convection space CS1 and the second convection space CS2 corresponding to the first hole part 321 may be connected to (or communicated with) the air gap 300s. Except for one side of each of the first convection space CS1 and the second convection space CS2 corresponding to the first hole part 321, the remaining portions may be spatially separated from the air gap 300s by the first to fourth guide portions 351, 352, 353, and 354 and may be spatially separated from each other within the air gap 300s by the fourth guide portion 354.

The first, third, and fourth guide portions 351, 353, and 354 may provide the second convection space CS2 within the air gap 300s. For example, the second convection space CS2 within the air gap 300s may be defined (or provided) to be surrounded by a second portion of the first guide portion 351, the third guide portion 353, and the fourth guide portion 354.

The 1-1^{th} hole 321h1 of the first hole part 321 may be disposed (or configured) in a lower side space (or a bottom space) of the first convection space CS1. The 1-1^{th} hole 321h1 of the first hole part 321 may be disposed (or configured) in the first convection space CS1 between ends of each of the second and fourth guide portions 352 and 354.

The 1-2^{th} hole 321h2 of the first hole part 321 may be disposed (or configured) in an upper side space (or a top space) of the first convection space CS1. The 1-2^{th} hole 321h2 of the first hole part 321 may be disposed (or configured) to be spaced apart from the 1-1^{th} hole 321h1 of the first hole part 321 along the short-side length direction Y of the display panel 100 (or the second cover 320) in the first convection space CS1. Except for one side (or a lower side) of the 1-2^{th} hole 321h2 of the first hole part 321, the remaining portion may be surrounded by the first, second, and fourth guide portions 351, 352, and 354.

The 2-1^{th} hole 322h1 of the second hole part 322 may be disposed (or configured) in the lower side space (or bottom space) of the second convection space CS2. The 2-1^{th} hole 322h1 of the second hole part 322 may be disposed (or configured) in the second convection space CS2 between ends of each of the third and fourth guide portions 353 and 354.

The 2-2^{th} hole 322h2 of the second hole part 322 may be disposed (or configured) in the upper side space (or top space) of the second convection space CS2. The 2-2^{th} hole 322h2 of the second hole part 322 may be disposed (or configured) to be spaced apart from the 2-1^{th} hole 322h1 of the second hole part 322 along the short-side length direction Y of the display panel 100 (or the second cover 320) in the second convection space CS2. Except for one side (or lower side) of the 2-2^{th} hole 322h2 of the second hole part 322, the remaining portion may be surrounded by the first, third, and fourth guide portions 351, 353, and 354.

A distance between the second guide portion 352 and the fourth guide portion 354 may decrease (or progressively decrease in a direction) from the 1-1^{th} hole 321h1 to (or toward) the 2-1^{th} hole 322h1 along the short-side length direction Y of the display panel 100 (or the second cover 320). In the first convection space CS1, a distance between the second guide portion 352 and the fourth guide portion 354 may decrease (or progressively decrease in a direction) from the 1-1^{th} hole 321h1 to (or toward) the 2-1^{th} hole 322h1 due to the inclined surface 352s and 354s1. In the first convection space CS1, a distance between the inclined surface 352s of the second guide portion 352 and the first inclined surface 354s1 of the fourth guide portion 354 may decrease (or progressively decrease in a direction) from the 1-1^{th} hole 321h1 to (or toward) the 2-1^{th} hole 322h1.

A distance between the third guide portion 353 and the fourth guide portion 354 may decrease (or progressively decrease in a direction) from the 1-2^{th} hole 321h2 to (or toward) the 2-2^{th} hole 322h2 along the short-side length direction Y of the display panel 100 (or the second cover 320). In the second convection space CS2, a distance between the third guide portion 353 and the fourth guide portion 354 may decrease (or progressively decrease in a direction) from the 1-2^{th} hole 321h2 to (or toward) the 2-2^{th} hole 322h2 due to the inclined surface 353s and 354s2. In the second convection space CS2, a distance between the inclined surface 353s of the third guide portion 353 and the second inclined surface 354s2 of the fourth guide portion 354 may decrease (or progressively decrease in a direction) from the 1-2^{th} hole 321h2 to (or toward) the 2-2^{th} hole 322h2.

FIG. 9 is a diagram for explaining heat dissipation of a display apparatus according to a second embodiment of the present disclosure.

Referring to FIGS. 7 to 9, the display apparatus 10 according to the second embodiment of the present disclosure includes the first and second convection spaces CS1 and CS2 formed (or provided) between the first cover 310 and the second cover 320 by an air guide member 350, the first hole part 321 and the second hole part 322, and thus, heat generated by driving each of the display panel 100 and the driving circuit part 150 may be dissipated by natural convection in each of the first and second convection spaces CS1 and CS2. For example, the display apparatus 10 according to the second embodiment of the present disclosure includes the first convection space CS1 formed (or provided) by the air guide member 350 and the 1-1^{th} hole part 321h1 of the first hole part 321 and the 2-1^{th} hole 322h1 of the second hole part 322, and the second convection space CS2 formed (or provided) by the air guide member 350 and the 1-2^{th} hole 321h2 of the first hole part 321 and the 2-2^{th} hole part 322h2 of the second hole part 322, and thus, heat generated by driving each of the display panel 100 and the driving circuit part 150 may be dissipated by natural convection phenomenon in the first and second convection spaces CS1 and CS2.

The heat generated by driving the display panel 100 is transferred to the first cover 310 of the rear cover 300 through the gap space 200s, and the heat transferred to the first cover 310 and the heat (or high temperature air) HA generated by driving the driving circuit part 150 may be dissipated according to the natural convection phenomenon of external air OA that flows into the first and second convection spaces CS1 and CS2 through the 1-1^{th} hole 321h1 and the 1-2^{th} hole 321h2 of the first hole part 321 from the external space, respectively, and flows out (or discharged) to the external space through the 2-1^{th} hole 322h1 and the 2-2^{th} hole 322h2 of the second hole part 322. Accordingly, the display apparatus 10 according to the second embodiment of the present disclosure may dissipate the heat transferred to the first cover 310 and the heat HA generated by driving the driving circuit part 150 according to the double-sided cooling effect due to natural convection and external convection in the first and second convection spaces CS1 and CS2.

Therefore, the display apparatus 10 according to the second embodiment of the present disclosure may further improve heat dissipation characteristics, and the heat dissipation characteristics (or heat dissipation performance) may be improved due to an increase in the heat dissipation surface area, and the temperature of the front surface of the display panel 100 may be reduced due to activation of natural convection in the air gap 300s.

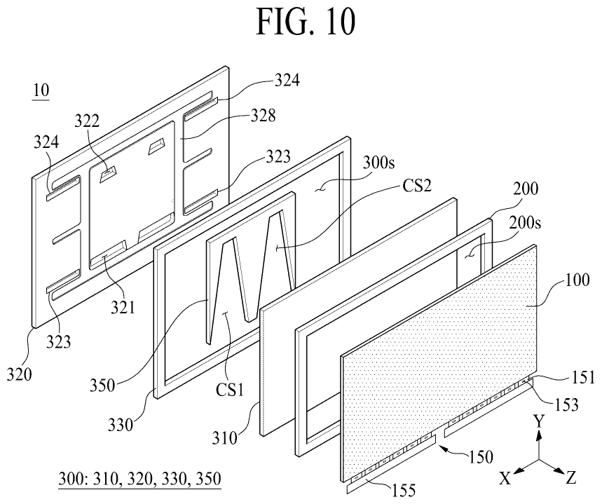

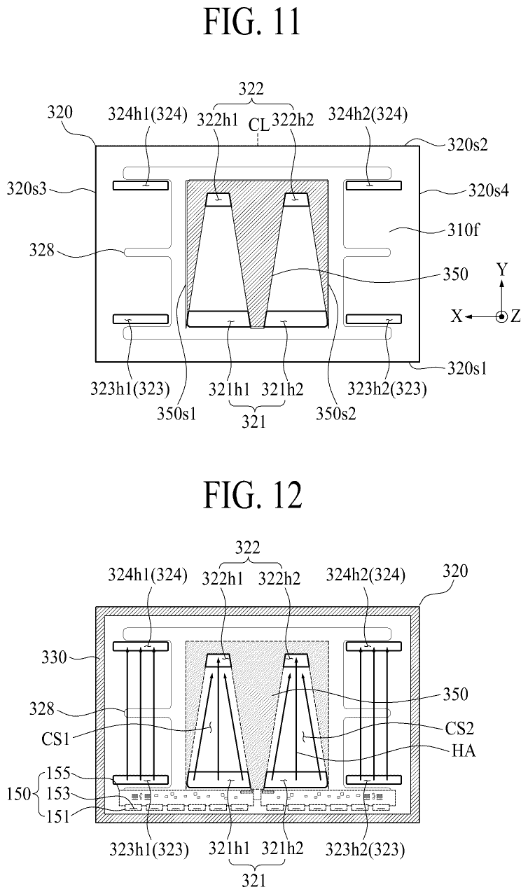

FIG. 10 is an exploded perspective view illustrating a display apparatus according to a third embodiment of the present disclosure. FIG. 11 is a diagram for explaining a second cover and an air guide member according to a third embodiment of the present disclosure illustrated in FIG. 10. FIGS. 10 and 11 illustrate an embodiment where a plate is additionally provided a third hole part and a fourth hole part at a second cover in the display apparatus described with reference to FIGS. 7 to 9. In the following description, therefore, the third hole part and the fourth hole part will be only described, the other elements are referred to by same reference numerals as FIGS. 7 to 9, and thus, their repetitive descriptions are omitted or will be briefly given. Accordingly, descriptions described with reference to FIGS. 2 to 9 may be included in descriptions of FIGS. 10 and 11.

Referring to FIGS. 10 and 11, in the display apparatus 10 according to the third embodiment of the present disclosure, the rear cover 300 or the second cover 320 may further include a third hole part 323 and a fourth hole part 324.

The third hole part 323 may be disposed around the first hole part 321 with the air guide member 350 therebetween. The third hole part 323 may be configured at a lower side of the second cover 320 adjacent to a second long side 320s2 of the second cover 320. The third hole part 323 may be configured to be adjacent to one or more printed circuit boards 155. For example, the one or more printed circuit boards 155 may be disposed at a rear edge portion of the display panel 100 adjacent to the third hole part 323.

The third hole part 323 may be configured to allow air to introduce (or flow) into an air gap 300s from an external space of the rear cover 300 (or the second cover 320). The third hole part 323 may be configured to penetrate the second cover 320 around the first hole part 321 with the air guide member 350 therebetween. The third hole part 323 may be formed to penetrate the second cover 320 along a thickness direction Z of the second cover 320. Accordingly, the external space of the second cover 320 may be communicated with (or connected to) the air gap 300s through the third hole part 323. Air in the external space of the rear cover 300 (or the second cover 320) may be introduced (or flowed) into the air gap 300s through the third hole part 323.

The fourth hole part 324 may be disposed around the second hole part 322 with the air guide member 350 therebetween. The fourth hole part 324 may be disposed (or configured) to be spaced apart from the third hole part 323 along a short-side length direction Y of the display panel 100 (or the second cover 320). The fourth hole part 324 may be configured at an upper side of the second cover 320 adjacent to the second long side 320s2 of the second cover 320. The fourth hole part 324 may be configured to allow air to flow out (or be discharged) to the external space of the rear cover 300 (or the second cover 320).

The fourth hole part 324 may be configured to penetrate the second cover 320 around the second hole part 322 with the air guide member 350 therebetween. The fourth hole part 324 may be formed to penetrate the second cover 320 along the thickness direction Z of the second cover 320. Accordingly, the external space of the second cover 320 may be communicated with (or connected to) the air gap 300s through the fourth hole part 324. Air (or high-temperature air) within the air gap 300s or air which is introduced (or flowed) into the air gap 300s through the fourth hole part 324 may flow out (or be discharged or dissipated) to the external space of the rear cover 300 (or the second cover 320) through the fourth hole part 324 by natural convection phenomenon in which the air rises in the opposite direction to the direction of gravity due to buoyancy.

The air guide member 350 may include a first side 350s1 adjacent to the first short side 350s3 of the second cover 320, and a second side 350s2 adjacent to the second short side 350s4 of the second cover 320.

The third hole part 323 according to an embodiment may include a 3-1^{th} hole 323h1 and a 3-2^{th} hole 323h2.

The 3-1^{th} hole 323h1 may be configured between a first short side 320s3 of the second cover 320 and a first side 350s1 of the air guide member 350 so as to penetrate the second cover 320. The 3-1^{th} hole 323h1 may be configured to be adjacent to one or more printed circuit boards 155. The 3-1^{th} hole 323h1 may be configured to penetrate the second cover 320 along the thickness direction Z of the second cover 320. Accordingly, the external space of the second cover 320 may be communicated with (or connected to) the air gap 300s through the 3-1^{th} hole 323h1. Air in the external space of the rear cover 300 (or the second cover 320) may be introduced (or flowed) into the air gap 300s through the 3-1^{th} hole 323h1.

The 3-2^{th} hole 323h2 may be configured between a second short side 320s4 of the second cover 320 and a second side 350s2 of the air guide member 350 so as to penetrate the second cover 320. The 3-2^{th} hole 323h2 may be configured to be adjacent to the one or more printed circuit boards 155. The 3-2^{th} hole 323h2 may be configured to penetrate the second cover 320 along the thickness direction Z of the second cover 320. Accordingly, the external space of the second cover 320 may be communicated with (or connected to) the air gap 300s through the 3-2^{th} hole 323h2. Air in the external space of the rear cover 300 (or the second cover 320) may be introduced (or flowed) into the air gap 300s through the 3-2^{th} hole 323h2.

The fourth hole part 324 according to an embodiment may include a 4-1^{th} hole 324h1 and a 4-2^{th} hole 324h2.

The 4-1^{th} hole 324h1 may be configured between the first short side 320s3 of the second cover 320 and the first side 350s1 of the air guide member 350 so as to penetrate the second cover 320. The 4-1^{th} hole 324h1 may be configured to be spaced apart from the 3-1^{th} hole 323h1 along a short-side length direction Y of the second cover 320 and adjacent to a second long side 320s2 of the second cover 320. The 4-1^{th} hole 324h1 may be configured to penetrate the second cover 320 along the thickness direction Z of the second cover 320. Accordingly, the external space of the second cover 320 may be communicated with (or connected to) the air gap 300s through the 4-1^{th} hole 324h1. Air (or high-temperature air) within the air gap 300s or air which is introduced (or flowed) into the air gap 300s through the 3-1^{th} hole 323h1 may flow out (or discharge or dissipate heat) to the external space of the rear cover 300 (or the second cover 320) through the 4-1^{th} hole 324h1 by natural convection phenomenon.

The 4-2^{th} hole 324h2 may be configured between a second short side 320s4 of the second cover 320 and a second side 350s2 of the air guide member 350 so as to penetrate the second cover 320. The 4-2^{th} hole 324h2 may be configured to be spaced apart from the 4-1^{th} hole 324h1 along the short-side length direction Y of the second cover 320 and adjacent to the second long side 320s2 of the second cover 320. The 4-2^{th} hole 324h2 may be configured to penetrate the second cover 320 along the thickness direction Z of the second cover 320. Accordingly, the external space of the second cover 320 may be communicated with (or connected to) the air gap 300s through the 4-2^{th} hole 324h2. Air (or high-temperature air) within the air gap 300s or air which is introduced (or flowed) into the air gap 300s through the 3-2^{th} hole 323h2 may flow out (or discharge or dissipate heat) to the external space of the rear cover 300 (or the second cover 320) through the 4-2^{th} hole 324h2 by natural convection phenomenon.

Each of the 3-1^{th} hole 323h1, the 3-2^{th} hole 323h2, the 4-1^{th} hole 324h1, and the 4-2^{th} hole 324h2 may have a line shape parallel to the second long side 310s2 of the second cover 320. The 3-1^{th} hole 323h1, the 3-2^{th} hole 323h2, the 4-1^{th} hole 324h1, and the 4-2^{th} hole 324h2 may have a same size, but is not limited thereto. For example, the 3-1^{th} hole 323h1 may have a size which is greater than the 4-1^{th} hole 324h1. The 3-2^{th} hole 323h2 may have a size which is greater than the 4-2^{th} hole 324h2. The 3-1^{th} hole 323h1 may have a width and a length which are greater than the 4-1^{th} hole 324h1. The 3-2^{th} hole 323h2 may have a width and a length which are greater than the 4-2^{th} hole 324h2.

The third hole part 323 and the fourth hole part 324 described above with reference to FIGS. 10 and 11 may be identically applied to the display apparatus 10 according to the first embodiment of the present disclosure described above with reference to FIGS. 2 to 6. For example, in the display apparatus 10 according to the first embodiment of the present disclosure, the rear cover 300 or the second cover 320 may be configured to include the third hole part 323 and the fourth hole part 324 described above with reference to FIGS. 10 and 11, and thus, their repetitive descriptions are omitted. Accordingly, descriptions of the third hole part 323 and the fourth hole part 324 described above with reference to FIGS. 10 and 11 may be included in the descriptions of the display apparatus 10 according to the first embodiment of the present disclosure described above with reference to FIGS. 2 to 6.

FIG. 12 is a diagram for explaining heat dissipation of a display apparatus according to a third embodiment of the present disclosure.

Referring to FIGS. 10 to 12, the display apparatus 10 according to the third embodiment of the present disclosure further includes the third hole part 323 and the fourth hole part 324 formed in the second cover 320 to be connected (or communicated) with the air gap 300s in the display apparatus 10 according to the second embodiment of the present disclosure, and thus, heat generated by driving each of the display panel 100 and the driving circuit part 150 may be additionally dissipated by natural convection phenomenon in the air gap 300s.

Therefore, the display apparatus 10 according to the third embodiment of the present disclosure may have a same effect as the display apparatus 10 according to the second embodiment of the present disclosure. The display apparatus 10 according to the third embodiment of the present disclosure may further improve the heat dissipation characteristics, and the heat dissipation characteristics (or heat dissipation performance) may further be improved due to the increase in the heat dissipation surface area, and the temperature of the front surface of the display panel 100 may further be reduced due to the activation of natural convection in the air gap 300s.

The inventors of the present disclosure conducted experiments on the heat dissipation characteristics (or performance) of the display apparatus according to the third embodiment of the present disclosure which includes the air guide member 350 and the first to fourth hole parts 321, 322, 323, and 324 and the heat dissipation characteristics (or performance) of a display apparatus 10 according to an experimental example which does not including the air guide member 350 and the first to fourth holes 321, 322, 323, and 324. For example, the display apparatus 10 according to the experimental example has a sealed (or closed) heat dissipation structure of an air gap according to a coupling member. Compared with the experimental example, the third embodiment of the present disclosure was able to confirm that the front temperature of the display panel was reduced by about 12%. In addition, compared with the experimental example, the third embodiment of the present disclosure was able to confirm that both the air speed in the air gap 300s and the air outflow speed were increased due to the air guide member 350.

It will be apparent to those skilled in the art that various modifications and variations can be made in the display apparatus of the present disclosure without departing from the technical idea or scope of the disclosure. Thus, it is intended that the present disclosure cover the modifications and variations of this disclosure provided they come within the scope of the claims and their equivalents.

What is claimed is:

1. A display apparatus, comprising:
a display panel configured to display an image and having long sides and short sides; and
a rear cover disposed at a rear surface of the display panel,
wherein the rear cover comprises:
a first cover disposed at the rear surface of the display panel;
a second cover configured to cover the first cover;
a coupling member configured to provide an air gap between the first cover and the second cover; and
an air guide member disposed between the first cover and the second cover within the air gap,
wherein the second cover includes a first hole part and a second hole part configured to be spaced apart from each other along a short-side length direction of the display panel, and
wherein the air guide member is configured to guide an air flow within the air gap from the first hole part to the second hole part.

2. The display apparatus of claim 1, wherein the air guide member is configured to increase a flow speed of air flowing from the first hole part to the second hole part within the air gap.

3. The display apparatus of claim 1, wherein:
the air guide member is configured to provide a convection space between the first hole part and the second hole part within the air gap, and
the convection space progressively narrows from the first hole part toward the second hole part.

4. The display apparatus of claim 1, wherein the first hole part has a size which is greater than the second hole part.

5. The display apparatus of claim 1, wherein:
the second cover includes a first long side and a second long side which are parallel to each other,
the first hole part is configured between the first long side of the second cover and a center of the second cover so as to penetrate the second cover, and
the second hole is configured at a portion between the second long side of the second cover and the center of the second cover so as to penetrate the second cover.

6. The display apparatus of claim 5, wherein the air guide member comprises:
a first guide portion disposed between the second long side of the second cover and the second hole part;
a second guide portion connected to a first side of the first guide portion and extending to a first side of the first hole part; and
a third guide portion connected to a second side of the first guide portion opposite the first side of the first guide portion and extending to a second side of the first hole part opposite the first side of the first hole part.

7. The display apparatus of claim 6, wherein:
the first to third guide portions are configured to provide a convection space between the first hole part and the second hole part within the air gap,
an extension line of a center of the first hole part is located at a center of the second hole part with respect to the short-side length direction of the display panel, and
a distance between the second guide portion and the third guide portion in the convection space progressively decreases in a direction from the first hole part to the second hole part.

8. The display apparatus of claim 6, wherein:
a cross-sectional size of each of the second guide portion and the third guide portion progressively decreases in a direction from the second hole part to the first hole part with respect to a long-side length direction of the display panel, and/or
each of the second guide portion and the third guide portion is disposed between the first hole part and the second hole part and includes an inclined surface which is inclined from the short-side length direction of the display panel.

9. The display apparatus of claim 5, wherein:
the first hole part includes a 1-1^{th} hole and a 1-2^{th} hole, which are spaced apart from each other along a long-side length direction of the second cover and configured to penetrate the second cover, and
the second hole part includes a 2-1^{th} hole and a 2-2^{th} hole, which are spaced apart from each other along the long-side length direction of the second cover and configured to penetrate the second cover.

10. The display apparatus of claim 9, wherein:
the 1-1^{th} hole has a size which is greater than the 2-1^{th} hole, and
the 1-2^{th} hole has a size which is greater than the 2-2^{th} hole.

11. The display apparatus of claim 9, wherein:
the air guide member is configured to provide a first convection space between the 1-1^{th} hole and the 2-1^{th} hole within the air gap, and to provide a second convection space between the 1-2^{th} hole and the 2-2^{th} hole within the air gap,
the first convection space progressively narrows in a direction from the 1-1^{th} hole toward the 2-1^{th} hole, and
the second convection space progressively narrows in a direction from the 1-2^{th} hole toward the 2-2^{th} hole.

12. The display apparatus of claim 9, wherein the air guide member comprises:
a first guide portion disposed between the second long side of the second cover and the second hole part;
a second guide portion connected to a first side of the first guide portion and extending to a first side of the 1-1^{th} hole;
a third guide portion connected to a second side of the first guide portion opposite the first side of the first guide portion and extending to a first side of the 1-2^{th} hole; and
a fourth guide portion connected to a third side of the first guide portion corresponding to an intermediate region between the 2-1^{th} hole and the 2-2^{th} hole and extending to a region between a second side of the 1-1^{th} hole and a second side of the 1-2^{th} hole.

13. The display apparatus of claim 12, wherein:
the first, second, and fourth guide portions are configured to provide a first convection space within the air gap, and the first, third, and fourth guide portions are configured to provide a second convection space within the air gap,
with respect to the short-side length direction of the display panel, an extension line of a center of the 1-1^{th} hole is located at a center of the 2-1^{th} hole, and an extension line of a center of the 1-2^{th} hole is located at a center of the 2-2^{th} hole,
a distance between the second guide portion and the fourth guide portion progressively decreases in a direction from the 1-1^{th} hole toward the 2-1^{th} hole in the first convection space, and
a distance between the third guide portion and the fourth guide portion progressively decreases in a direction from the 1-2^{th} hole toward the 2-2^{th} hole in the second convection space.

14. The display apparatus of claim 12, wherein:
a cross-sectional size of each of the second, third, and fourth guide portions progressively decreases in a direction from the second hole part to the first hole part with respect to a long-side length direction of the display panel, and/or
each of the second, third, and fourth guide portions is disposed between the first hole part and the second hole part and includes an inclined surface which is inclined from the short-side length direction of the display panel.

15. The display apparatus of claim 1, wherein the second cover further comprises:
a third hole part disposed around the first hole part with the air guide member therebetween; and
a fourth hole part disposed around the second hole part with the air guide member therebetween.

16. The display apparatus of claim 15, wherein:
the second cover includes a first short side and a second short side which are parallel to each other,
the air guide member includes a first side adjacent to the first short side of the second cover, and a second side adjacent to the second short side of the second cover,
the third hole part includes a 3-1^{th} hole configured between the first short side of the second cover and the first side of the air guide member so as to penetrate the second cover, and a 3-2^{th} hole configured between the second short side of the second cover and the second side of the air guide member so as to penetrate the second cover, and
the fourth hole part includes a 4-1^{th} hole configured between the first short side of the second cover and the first side of the air guide member so as to penetrate the second cover, and a 4-2^{th} hole configured between the second short side of the second cover and the second side of the air guide member so as to penetrate the second cover.

17. The display apparatus of claim 1, wherein one or more of the coupling member and the air guide member includes a conductive material or a conductive adhesive member.

18. The display apparatus of claim 1, further comprising a driving circuit part including one or more printed circuit boards electrically connected to the display panel,
wherein the one or more printed circuit boards are disposed at a rear edge portion of the display panel adjacent to the first hole part.

19. The display apparatus of claim 18, wherein:
the second cover covers the one or more printed circuit boards, and
a space between the second cover and the one or more printed circuit boards is connected to the air gap.

20. The display apparatus of claim 1, further comprising a connection member configured to provide a gap space between the display panel and the first cover.
